(19) United States
(12) Patent Application Publication
(10) Pub. No.: US 2024/0332192 A1
(43) Pub. Date: Oct. 3, 2024

(54) PACKAGE STRUCTURE

(71) Applicant: Advanced Semiconductor Engineering, Inc., Kaohsiung (TW)

(72) Inventors: Po-I WU, Kaohsiung (TW); Chun-Yen TING, Kaohsiung (TW); Hung-Chun KUO, Kaohsiung (TW); Jung Jui KANG, Kaohsiung (TW); Chiu-Wen LEE, Kaohsiung (TW); Shih-Yuan SUN, Kaohsiung (TW)

(73) Assignee: Advanced Semiconductor Engineering, Inc., Kaohsiung (TW)

(21) Appl. No.: 18/128,988

(22) Filed: Mar. 30, 2023

(51) Int. Cl. H01L 23/538; G02B 6/12; H01L 23/00; H01L 23/36; H01L 25/16

(52) U.S. Cl. CPC H01L 23/5381; G02B 6/12004; H01L 23/36; H01L 24/16; H01L 25/167; H01L 23/49816; H01L 24/32; H01L 24/73; H01L 2224/16145; H01L 2224/16225; H01L 2224/32225; H01L 2224/73204

(57) ABSTRACT

A package structure is provided. The package structure includes a bridge component, a photonic processing unit, and an electrical device. The photonic processing unit is disposed over the bridge component. The electrical device is disposed over the bridge component. The bridge component is configured to optically couple with the photonic processing unit and electrically connect with the electronic component.

### BACKGROUND

### 1. Field of the Disclosure

The present disclosure relates to a package structure.

### 2. Description of the Related Art

A package including a processing unit, a memory, and a bridge unit electrically connected the processing unit with the memory is known. However, the bandwidth of the electrical transmission provided by the bridge unit may be insufficient for the communication between the processing units and memory with more advanced technology or nodes.

### SUMMARY

In some embodiments, a package structure includes a bridge component, a photonic processing unit, and an electrical device. The photonic processing unit is disposed over the bridge component. The electrical device is disposed over the bridge component. The bridge component is configured to optically couple with the photonic processing unit and electrically connect with the electronic component.

In some embodiments, a package structure includes a signal transmission component and an electro-optic conversion unit. The signal transmission component includes a plurality of optical I/O units and a plurality of electrical I/O units. The electro-optic conversion unit is configured to convert optical signals to electrical signals or convert the electrical signals to the optical signals. The signal transmission component includes a first transmission path configured to transmit the optical signals from or to the optical I/O units, and a second transmission path configured to transmit the electrical signals from or to the electrical I/O units. The electro-optic conversion unit connects with the first transmission path or the second transmission path or both.

In some embodiments, a package structure includes a bridge component, a photonic processing unit, and an optical component. The bridge component includes a first surface and a second surface different from the first surface. The photonic processing unit is disposed over and optically connects with the first surface of the bridge component. The optical component optically connects with the second surface of the bridge component. The optical component communicates with the photonic processing component through the bridge component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a cross-sectional view of a package structure according to some embodiments of the present disclosure.

FIG. 2 is a cross-sectional view of a package structure according to some embodiments of the present disclosure.

FIG. 3 is a cross-sectional view of a package structure according to some embodiments of the present disclosure.

FIG. 4 is a cross-sectional view of a package structure according to some embodiments of the present disclosure.

FIG. 5 is a cross-sectional view of a package structure according to some embodiments of the present disclosure.

FIG. 5A is a bottom view of a set of device according to some embodiments of the present disclosure.

FIG. 6 is a cross-sectional view of a package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

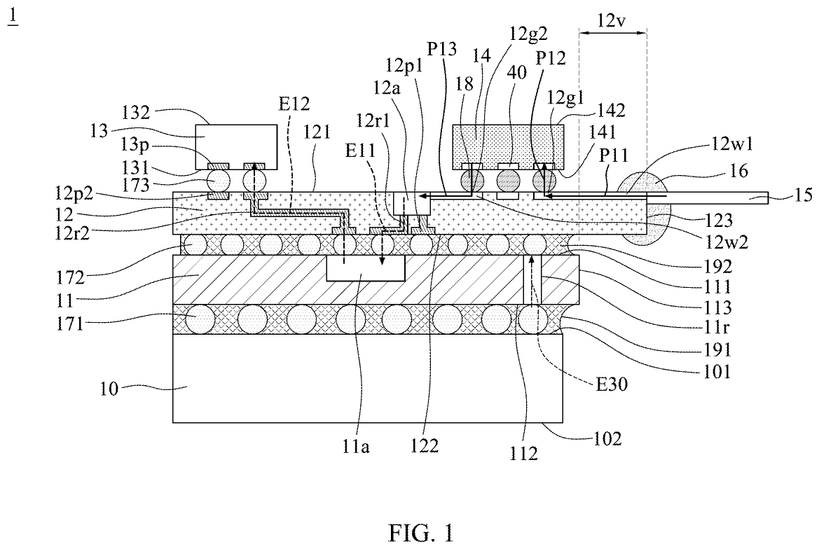

FIG. 1 is a cross-sectional view of a package structure 1 according to some embodiments of the present disclosure. The package structure 1 may include a carrier 10, a wiring structure 11, a component 12, an electrical component 13, a photonic component 14, an optical component 15, an adhesive material 16, a plurality of connection elements 171, 172, and 173 (or electrical connection elements), a plurality of connection elements (or optical connection elements) 18, a protective element 191, and a protective element 192.

The carrier (or a substrate) 10 may have a surface 101 and a surface 102 opposite to the surface 101. In some embodiments, the carrier 10 may be or include, for example, a printed circuit board (PCB), such as a paper-based copper foil laminate, a composite copper foil laminate, or a polymer-impregnated glass-fiber-based copper foil laminate, or so on. In some embodiments, the carrier 10 may include a semiconductor substrate including silicon, germanium, or other suitable materials. In some embodiments, the carrier 10 may be or include a redistribution structure.

The wiring structure 11 may be disposed over the carrier 10. The wiring structure 11 may have a surface 111 facing the component 12, a surface 112 opposite to the surface 111 and facing the carrier 10, and a lateral surface 113 extending between the surface 111 and the surface 112. The carrier 10 may be electrically connected to the wiring structure 11 through the connection elements 171. The connection elements 171 may be disposed between the surface 112 of the wiring structure 11 and the surface 101 of the carrier 10. The connection elements 17 may include solder balls, controlled collapse chip connection (C4) bumps, a ball grid array (BGA), or a land grid array (LGA). The wiring structure 11 may be or include an interposer. The wiring structure 11 may be or include a silicon interposer. The wiring structure 11 may include one or more dielectric layers and conductive element(s) (e.g., conductive layer, conductive trace, conductive pad, and/or conductive via) disposed on or embedded in the dielectric layer(s). The wiring structure 11 may include one or more conductive pillars 11r extending from the surface 111 of the wiring structure 11 to the surface 112 of the wiring structure 11. The conductive pillars 11r may penetrate through the wiring structure 11. The conductive pillars 11r may be configured to transmit a power signal E30 from the carrier 10 to the component 12. In some embodiments, the wiring structure 11 may be or include an interposer, such as a silicon (Si) interposer.

The component 12 may be disposed over the wiring structure 11. In some embodiments, the component 12 is flip-chip bonded to the wiring structure 11. In some embodiments, at least a portion (e.g., 12v) of a projection of the component 12 in a vertical direction does not overlap the wiring structure 11. In some embodiments, the portion 12v in a vertical direction does not overlap the photonic component 14. In some embodiments, a portion 12v of the component 12 extends outwardly with respect to the lateral surface 113 of the wiring structure 11. In some embodiments, the portion 12v of the component 12 overhangs the wiring structure 11. The component 12 may have a surface (or an upper surface) 121 and a surface (or a lower surface) 122 opposite to the surface 121. The surface 122 of the component 12 may face the surface 111 of the wiring structure 11. The component 12 may have a surface (or a lateral surface) 123 extending between the surface 121 and the surface 122 of the component 12 and located at the portion 12v. The surface 123 is different from the surface 121 or 122.

The portion 12v of the component 12 may be referred to an overhang or an overhang portion. In some embodiments, the portion (or the overhang portion) 12v of the component 12 may be optically coupled with the optical component 15 through grating coupling or edge coupling, etc. The optical component 15 may be or include an optical fiber. The optical component 15 may be or include a fiber array unit including a plurality of optical fibers. In FIG. 1, the optical component 15 may be connected or attached to the lateral surface 123 by an adhesive material (or protective material) 16. The optical component 15 may be optically coupled with the component 12 and communicate with the photonic processing unit 14. The adhesive material (or protective material) 16 may encapsulate a coupling end of the optical component 15. The adhesive material (or protective material) 16 may include epoxy or other another suitable polymeric material. The adhesive material (or protective material) 16 may have a coefficient of thermal expansion (CTE) different from that of the protective element 191.

In some embodiments, the component 12 may have a thickness in a range from about 200 μm to about 300 μm, such as, 200 μm, 210 μm, 220 μm. 230 μm, 240 μm, 250 μm, 260 μm, 270 μm, 280 μm, 290 μm, or 300 μm, but is not limited thereto. In some embodiments, the portion 12v of the component 12 may have a length in a range from about 30 μm to about 200 μm, such as, 30 μm, 50 μm, 80 μm, 100 μm, 120 μm, 150 μm, 180 μm, or 200 μm, but is not limited thereto.

In some embodiments, the component 12 may be configured to function as a bridge component (or bridge unit) connecting the photonic component 14 and the electronic component 13. In some embodiments, the component 12 may be configured to transmit signal(s) (e.g., data signal(s)) between the photonic component 14 and the electronic component 13. The component 12 may be configured to transmit signal(s) (e.g., data signal(s)) between the photonic component 14 and the optical component 15. The component 12 may have a first transmission path configured to transmit optical signals P11 or P13 (e.g., optical data signals) and a second transmission path configured to transmit electric signals E12 (e.g., electric data signals). In some embodiments, the first transmission path is configured to transmit optical signals P13 from or to the photonic component 14 or configured to transmit optical signals P11 from or to the optical component 15. In some embodiments, the first transmission path configured to transmit the optical signals P11 from or to the optical component 15 may be referred to as “third transmission path”. In some embodiments, the second transmission path is configured to transmit electric signals E12 (e.g., electric data signals) from or to the electronic component 13. In some embodiments, the component 12 may further have a transmission path (i.e., the fourth transmission path) configured to transmit power signals (not shown) received from the wiring structure 11. In some embodiments, the component 12 includes or consists essentially of transmission paths for transmitting electrical signals, optical signals and power signals and an electro-optic conversion unit to convert electrical signals to optical signals or convert optical signals to electrical signals. In some embodiments, the component 12 may not include additional active device(s). In some embodiments, the component 12 may be referred to as a bridge component or a signal transmission component.

The component 12 may include one or more transmission path(s) for transmitting optical signal(s). In some embodiments, the component 12 may include a waveguide 12w1 and a waveguide 12w2 located at or adjacent to the surface 121 of the component 12. The waveguide 12w1 may include one or more I/O units (or optical I/O units) 12g1. The I/O units 12g1 may optically couple with the connection elements (optical connection elements) 18. The waveguide 12w1 may optically couple with the photonic component 14 through the optical connection elements 18. The optical connection elements 18 may be disposed between the photonic component 14 and the component 12. The optical connection elements 18 may include material for guiding the light (e.g., optical signals) therethrough. The optical connection elements 18 may include an optical bump configured to optically transmit the light (e.g., optical signals) between the component 12 and the photonic component 14. In some embodiments, the term “I/O units” used in the present disclosure may be referred to as “I/O terminals.” In some embodiments, the term “optical bump” used in the present disclosure may be referred to as “photonic bump.”

The waveguide 12w1 may optically couple with the optical component 15, for example, through grating coupling or edge coupling. The component 12 may include an edge coupler, grating coupler, or v-groove(s) at the lateral surface 123, the upper surface 121 or the lower surface 122 so as to couple the waveguide 12w1 with the optical component 15.

The waveguide 12w1 may be configured to transmit an optical signal P11 from or to the optical component 15. In some embodiments, the waveguide 12w1 (or the I/O units 12g1) may be configured to transmit the optical signal P11 between the photonic component 14 and the optical component 15, for example, to transmit the optical signal P11 from the optical component 15 to the photonic component 14 through the connection element 18 and vice versa. The I/O units 12g1 may include a grating structure transmitting or receiving the optical signals P12. The optical signal P11 may be associated with the optical signal P12, or in some cases, identical to the optical signal P12. The waveguide 12w1 may include a beam splitter (or divider) to split a beam (or the optical signal P11) into a plurality of beams (including the optical signal P12. Thus, the intensity of the optical signals P11 and P12 may be different but the wavelength/wave number/frequency may be substantially the same.

The waveguide 12w2 may include one or more I/O units (or optical I/O units) 12g2. The I/O units 12g2 may optically couple with the connection elements (optical connection elements) 18. The waveguide 12w2 may optically couple with the photonic component 14 through the optical connection elements 18.

The waveguide 12w1 and the waveguide 12w2 may include a dielectric material, such as silicon oxide, silicon nitride, or the like. In some embodiments, the waveguide 12w1 and the waveguide 12w2 may include a core made of silicon or silicon nitride for signal (e.g., light wave) propagation and a cladding layer made of oxide (e.g., silicon oxide) or polymer.

The photonic component 14 may be disposed over the component 12. The photonic component 14 may have a surface 141 facing the surface 121 of the component 12 and a surface 142 opposite to the surface 141. In some embodiments, the photonic component 14 may be or include a photonic processing unit. The photonic processing unit 14 may be configured to process the optical signal P12 and/or the optical signal P13. The photonic processing unit 14 may include a photonic computing processer. The photonic processing unit 14 may include one or more photonic devices to modulate, polarize, or transmit the optical signal P12 and/or the optical signal P13. In some embodiments, the photonic processing unit 14 may be configured to receive the optical signal 11 (or P12) transmitted from the optical component 15, process the optical signal P12 to generate an optical signal P13 and transmit the optical signal 13 to the component 12 (or the I/O units 12g2 of the waveguide 12w2 of the component 12) through the optical connection elements 18. The I/O units 12g2 may include a grating structure transmitting or receiving the optical signals P13. The photonic processing unit 14 may include a plurality of I/O units (or optical I/O units) 40 located at the surface 141 and optically coupled with the optical connection elements 18. The I/O units 40 may include a grating structure transmitting or receiving the optical signals P12 and P13.

The component 12 may include an electro-optic conversion unit 12a, a circuit structure 12r1, and a circuit structure 12r2. The electro-optic conversion unit 12a is configured to convert optical signals to electrical signals or convert the electrical signals to the optical signals. The circuit structures 12r1 and 12r2 may be the transmission paths for electrical signals. The circuit structures 12r1 and 12r2 may be embedded in the component 12. The electro-optic conversion unit 12a may be located between the photonic component 14 and the electronic component 13. In some embodiments, the electro-optic conversion unit 12a may be closer to the electronic component 13 than to the photonic component 14 so that a majority of data transmission can be done through optical transmission paths of the component 12 which allows for high bandwidth signal transmission. The circuit structure 12r1 may electrically connect the electro-optic conversion unit 12a and the wiring structure 11. The wiring structure 11 may include one or more electronic device(s), such as a modulator driver (DRV) or modular 11a. In some embodiments, the modulator driver (DRV) or modulator 11a may be embedded in the wiring structure 11. The wiring structure 11 may have a thickness in a range from about 775 μm to about 800 μm, but is not limited thereto; and the modulator driver (DRV) or modulator 11a may have a thickness in a range from about 700 μm to about 720 μm but is not limited thereto. In some embodiments, the modulator driver (DRV) or modulator 11a may include a passive component, such as a resistor, or an active component, such as an amplifier. The circuit structure 12r1 may include one or more I/O units (or electrical I/O units) 12p1 electrically connected to the modulator driver (DRV) or modulator 11a of the wiring structure 11 through the connection elements 172. The one or more I/O units 12p1 may be disposed at the surface 122 of the component 12. The circuit structure 12r2 may electrically connect the modulator 11a of the wiring structure 11 and the electronic component 13 through the connection elements 172. The circuit structure 12r2 may include one or more I/O units (or electrical I/O units) 12p2 electrically connected to the electronic component 13 through the connection elements 173. The one or more I/O units 12p2 may be disposed at the surface 121 of the component 12. The electro-optic conversion unit 12a may be located between the optical I/O units 12g1 or 12g2 and the electrical I/O units 12p1 or 12p2.

In some embodiments, the electro-optic conversion unit 12a may be connected to the first transmission path or the second transmission path or both. The first transmission path is configured to transmit optical signals P13 from or to the optical I/O units 12g2. The second transmission path is configured to transmit electrical signals E12 from or to the electrical I/O units 12p2.

The optical I/O units 12g1 (or 12g2) and the electrical I/O units 12p1 (or 12p2) may be of different densities. The optical I/O units 12g1 (or 12g2) may have a bandwidth per unit area higher than that of electrical I/O units 12p1 (or 12p2). The I/O units 12p1 and 12p2 may include conductive pads. The I/O units 12p1 and 12p2 and the circuit structures 12r1 and 12r2 may each include metal such as copper (Cu), gold (Au), aluminum (Al), titanium (Ti) or the like. The insulating layer of the wiring structure 12 may include pre-impregnated composite fibers (e.g., a pre-preg material).

The electro-optic conversion unit 12a may be configured to optically couple with the waveguide 12w2. The electro-optic conversion unit 12a may include a photodiode configured to covert an optical signal to an electrical signal. The electro-optic conversion unit 12a may include a laser diode.

The electro-optic conversion unit 12a may be configured to receive the optical signal P13 from the photonic component 14 through the waveguide 12w2. The electro-optic conversion unit 12a may be configured to convert the optical signal P13 to an electrical signal E11. The electro-optic conversion unit 12a may be configured to transmit the electrical signal E11 to the circuit structure 12r1. The circuit structure 12r1 may transmit the electrical signal E11 to the modulator driver (DRV) or modulator 11a which may modulate or amplify the electrical signal E11 to an electrical signal E12. The modulator driver (DRV) or modulator 11a may be configured to transmit the electrical signal E12 to the electronic component 13 through the circuit structure 12r2. In some embodiments, the electrical signal E11 may be referred as to the electrical signal E12 for the purpose of explaining the signal transmission. Therefore, the electro-optic conversion unit 12a is configured to receive the optical signals P13 from the photonic component 14 through the optical I/O units 12g2, convert the optical signals P13 to the electrical signals E11 or electrical signals E12 (after modulation or amplification), and transmit the electrical signals E11/E12 to the electronic component 13 through the electrical I/O units 12p2. It should be noted that the component 12 is capable of bidirectional signal transmission. Thus, the electro-optic conversion unit 12a may be configured to receive the electrical signal E11 (came from the electrical signal E12 and modulated or amplified by the modulator driver (DRV) or modulator 11a), convert the electrical signal E11 to an optical signal P13 and transmit the optical signal P13 to the photonic component 14 through the waveguide 12w2.

The electronic component 13 may be disposed over the component 12. The electronic component 13 may have a surface 131 facing the component 12 and a surface 132 opposite to the surface 131. The electronic component 13 may include a plurality of I/O units 13p at the surface 131 electrically connected to the component 12 (e.g., the circuit structure 12r2 of the component 12) through the connection elements 173. The I/O units 13p may be referred to as electrical I/O units. The I/O units 13p may include conductive pads. The electronic component 13 may be or include a memory unit (or a data storage unit). The electronic component 13 may be or include a memory. The electronic component 13 may be or include dynamic random access memory (DRAM), static random access memory (SRAM), magnetoresistive random access memory (MRAM), flash memory, high bandwidth memory (HBM), or other suitable memory.

The photonic component 14 and the electronic component 13 process different types of signals. The photonic component 14 may process optical signals and the electronic component 13 may process electrical signals. The photonic component 14 may be configured to communicate with the electronic component 13 through the component 12. The photonic component 14 may be configured to read and/or write the data stored in the electronic component 13 and transmitted through the component 12. In some embodiments, the component 12 may be configured to convert a first command (e.g., the optical signal P13 from the photonic component 14) to a second command (e.g., the electrical signal E12) that is compatible with the electronic component 13. In some embodiments, the electronic component 13 may transmit data (electrical signals) to the component 12, based on the commands from the photonic component 14 (i.e., P13 and E12), and then the data is converted from electrical signal(s) to optical signal(s) by the electro-optic conversion unit 12a and transmitted to the photonic component 14. The component 12 provides a hybrid transmission path (at least including electrical and optical transmission paths) for bidirectional transmitting signals between the photonic component 14 and the electronic component 13. Thus, the component 12 is a bridge, buffer, or interface that realizes the communication between a photonic component, element or structure (e.g., the photonic component 14) and an electronic component, element or structure (e.g., electronic component 13). With the nature of high bandwidth of optical transmission brought by the photonic component 14 and the component 12, the bandwidth and efficiency of the data transmission in the package structure 1 may significantly increase.

In some embodiments, with the optical I/O units 12g1 and 12g2 and the electrical I/O units 12p2 at the same surface, i.e., the surface 121, the component 12 is capable of connecting a photonic component, element or structure (e.g., the photonic component 14) and an electronic component, element or structure (e.g., the electronic component 13) arranged at the same side of the component 12. In some embodiments, with the electrical I/O units 12p1 at the surface 122, different from the surface 121, the component 12 is capable of connecting an electronic component, element or structure (e.g., the wiring structure 11).

The protective element 191 may be disposed between the surface 101 of the carrier 10 and the surface 112 of the wiring structure 11. The protective element 191 may surround or enclose the connection elements 171. Owing to capillary action, the protective element 191 may flow along the surface 101 of the carrier 10 and the surface 112 of the wiring structure 11 before curing. The protective element 191 may contact the surface 101 of the carrier 10 and the surface 112 of the wiring structure 11 and have a curved lateral surface (not denoted) after curing.

The protective element 192 may be disposed between the surface 111 of the wiring structure 11 and the surface 122 of the component 12. The protective element 192 may surround or enclose the connection elements 172. Owing to capillary action, the protective element 192 may flow along the surface 111 of the wiring structure 11 and the surface 122 of the component 12 before curing. The protective element 192 may contact the surface 111 of the wiring structure 11 and the surface 122 of the component 12 and have a curved lateral surface (not denoted) after curing.

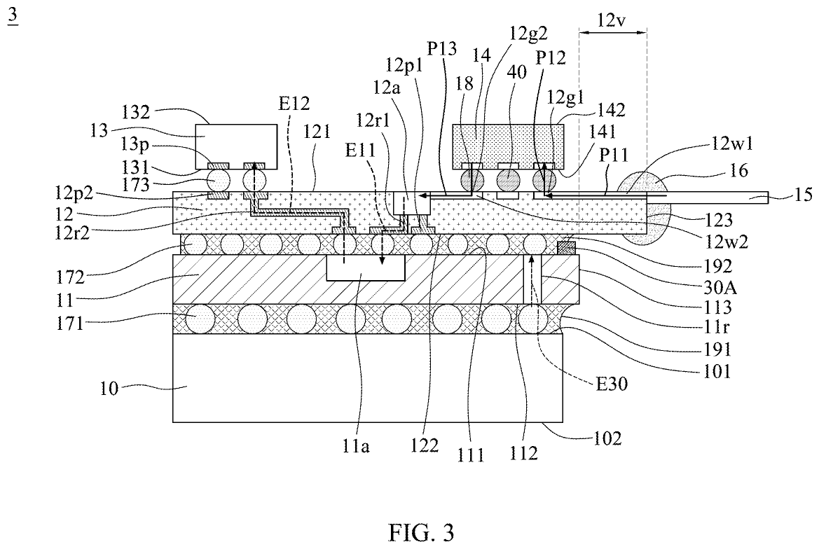

In some cases where the protective element 191 contacts the protective element 192, a crack between the protective element 192 and the photonic component 14 may occur. In the present disclosure, the amount/volume/size of the protective elements 191 and 192 are controlled so that they can sufficiently surround or enclose the connection elements 171 and 172, respectively, without contacting each other due to an overflow of the protective elements 191 and 192 (especially, the protective element 192) before curing. Furthermore, to avoid the contact between the protective elements 191 and 192, a portion of the wiring structure 11 may protrude from the surface 111 of the wiring structure 11 and function as a barrier to block the overflow of the protective element 192 before curing. In some embodiments, the length of the wiring structure 11 may be greater than the length of the carrier to prevent from the overflow issue of the protective element 192. Some other details will be discussed below with respect to the embodiments illustrated in FIG. 3.

The protective element 191 and the protective element 192 may be or include an encapsulant. The protective element 191 and the protective element 192 may be, for example, an underfill, but is not limited thereto. The protective element 191 and the protective element 192 may include an epoxy resin having fillers, a molding compound (e.g., an epoxy molding compound or other molding compound), polyimide, a phenolic compound or material, a material with a silicone dispersed therein, or a combination thereof.

In some embodiments, the package structure 1 may further include a molding compound (encapsulant) to cover, encapsulate or enclose the photonic component 14, the electronic component 13, the connection elements 173, and the connection elements 18 to protect them or to reinforce the stiffness of the package structure 1. The molding compound may should be spaced apart from the overhanging portion 12v or spaced apart at least from an area of the overhanging portion which is optical coupling with the optical component 15. The molding compound may not contact the adhesive material 16 to prevent from a cracking therebetween.

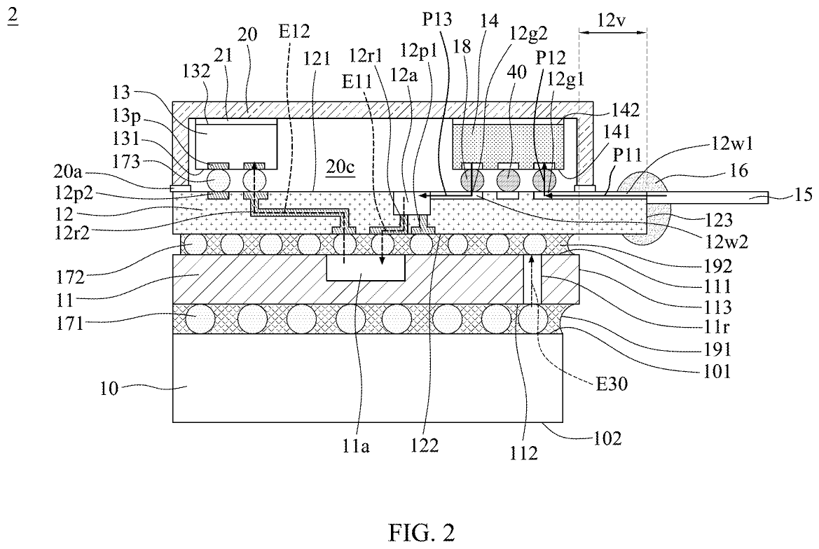

FIG. 2 is a cross-sectional view of a package structure 2 according to some embodiments of the present disclosure. The package structure 2 in FIG. 2 is similar to the package structure 1 in FIG. 1 with differences therebetween as follows.

The package structure 2 may further include a lid (e.g., a metal lid) 20 disposed over the component 12. The lid 20 may be attached to the surface 121 of the component 12 through an adhesive material 20a. The lid 2 may define a cavity 20c to accommodate the photonic component 14 and the electronic component 13. The lid 20 may be attached to the surface 142 of the photonic component 14 and the surface 132 of the electronic component 13 through an adhesive material 21. The adhesive material 21 may be or include thermal interface material (TIM). The adhesive material 21 may include a conductive glue, such as tin-based glue. The lid 20 may function as a heat sink or connects to a further heat sink. The lid (or the heat sink) 20 may be thermally connected to the photonic component 14 and the electronic component 13. The lid 20 may be configured to dissipate heat from the package structure 2. In particular, the lid 20 may dissipate heat from the photonic component 14 and the electronic component 13 through the adhesive material 21. In some embodiments, the lid (or the heat sink) 20 may be thermally connected to the component 12 for heat dissipation.

FIG. 3 is a cross-sectional view of a package structure 3 according to some embodiments of the present disclosure. The package structure 3 in FIG. 3 is similar to the package structure 1 in FIG. 1 with differences therebetween as follows.

The package structure 3 may include a blocking structure 30A disposed on the surface 111 of the wiring structure 11. In some embodiments, the blocking structure 30A may include a wall structure. In some embodiments, the blocking structure 30A may include a protrusion from the surface 111 of the wiring structure 11. In some embodiments, the blocking structure 30A may extend between the surface 111 of the wiring structure 11 and the surface 122 of the component 12. In some embodiments, the blocking structure 30A is configured to block the protective element 192 from overflowing or contacting the lateral surface 113 of the wiring structure 11. The blocking structure 30A can be made of suitable materials. In some embodiments, the blocking structure 30A may include a solder resist layer.

According to some embodiments of the present disclosure, the blocking structure 30A can prevent the material of the protective element 192 (e.g., a protective material) from overflowing into the overhang 12v of the component 12 during manufacture of the package structure 3. As a result, the overhang 12v can be free from contacting with the protective element 192. In other words, the blocking structure 30A may prevent the protective element 192 from approaching or contacting the lateral surface 123 of the component 12. Therefore, the optical coupling efficiency of the package structure 3 and the optical component 15 will not be affected by the protective element 192. The yield of the package structure 3 can be improved. Furthermore, the blocking structure 30A may prevent the protective element 192 from contacting with the adhesive material 16, thereby preventing any cracking therebetween (induced by the CTE mismatch). At the same time, the blocking structure 30A may prevent from the contact between the protective elements 191 and 192 as discussed above.

In some embodiments where the blocking structure 30A does not contact the surface 122 of the component 12, a relatively small gap between an upper surface of the blocking structure 30A and the surface 122 of the component 12 may magnify the capillary effect and attract the protective material into the gap. Hence, the size of the blocking structure 30A may be designed to reduce such capillary effect. For example, blocking structure 30A may be relatively wide and at the same time relatively thin.

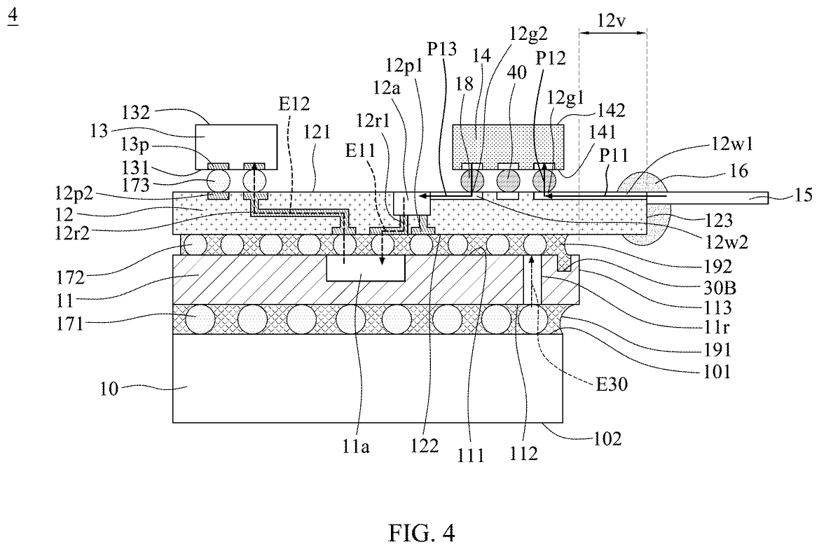

FIG. 4 is a cross-sectional view of a package structure according to some embodiments of the present disclosure. The package structure 4 in FIG. 4 is similar to the package structure 1 in FIG. 1 with differences therebetween as follows.

The package structure 4 in FIG. 4 may include a blocking structure 30B at the surface 111 of the wiring structure 11. The blocking structure 30B is recessed from the surface 111 of the wiring structure 11. In some embodiments, the blocking structure 30B may be or include a trench recessed from the surface 111 of the wiring structure 11. In some embodiments, a portion of the protective element 192 may be filled into the trench (i.e., the blocking structure 30B) and retained therein so that the blocking structure 30B may prevent from the contact between the protective elements 191 and 192.

According to some embodiments of the present disclosure, the blocking structure 30B can prevent the material of the protective element 192 (e.g., a protective material) from overflowing into the overhang portion 12v of the component 12 during manufacture of the package structure 4. The blocking structure 30B may also deteriorate the capillary action in the neighboring area. The excess protective material may flow and fill in the trench, and the overhang portion 12v, as well as the lateral surface 123, of the component 12 can be free from contacting with the protective element 192. In other words, the blocking structure 30B may prevent the protective element 192 from approaching the lateral surface 123 of the component 12. Therefore, the optical coupling efficiency of the package structure 4 and the optical component 15 and the yield of the package structure 4 can be increased. Furthermore, the blocking structure 30B may block the protective element 192 from contacting with the adhesive material 16 or the protective element 191, thereby preventing any cracking therebetween.

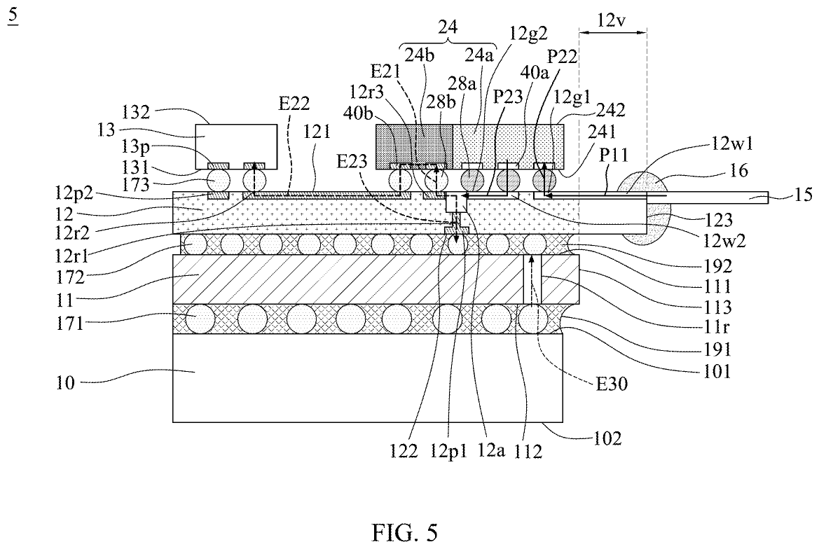

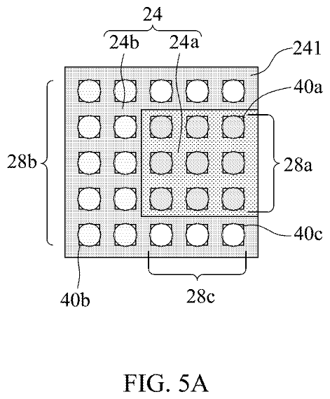

FIG. 5 is a cross-sectional view of a package structure 5 according to some embodiments of the present disclosure. The package structure 5 may include a carrier 10, a wiring structure 11, a component 12, an electronic component 13, a set of devices 24 (two or more devices), an optical component 15, an adhesive material 16, a plurality of electrical connection elements 171, 172, and 173, a plurality of optical connection elements 28a, a plurality of connection elements 28b, a protective element 191, and a protective element 192. The carrier 10, the wiring structure 11, the component 12, the electronic component 13, the optical component 15, the adhesive material 16, the plurality of electrical connection elements 171, 172, and 173, the protective element 191, and the protective element 192 may be similar to those of the package structure 1 in FIG. 1. Therefore, some detailed descriptions may refer to the corresponding paragraphs and are not repeated hereinafter for conciseness.

The devices 24 may have a lower surface 241 facing the component 12 and an upper surface 242 opposite the lower surface 241. The upper surfaces of the devices 24 may be not at the same height. The devices 24 of the package structure 5 may include a photonic component 24a and an electrical device (such as a modulator driver (DRV) or modulator) 24b. In some embodiments, the photonic component 24a may be adjacent to or physically contact with the electronic device 24b. In some embodiments, this a gap between the photonic component 24a and the electronic device 24b. In some embodiments, the photonic component 24a may be integrated with the electronic device 24b.

The connection elements 28a may be optical connection elements and may be disposed between the photonic component 24a and the component 12. The photonic component 24a may include a plurality of I/O units (or optical I/O units) 40a at the surface 241 of the photonic component 24a. The photonic component 24a (or the I/O units 40a) may optically couple with the component 12 (or the waveguides 12w1 and 12w2) through the optical connection elements 28a. The I/O units 40a may include a grating structure transmitting or receiving an optical signal from the component 12 or the optical component 15.

The connection elements 28b may be electrical connection elements and may be disposed between the electronic device 24b and the component 12. The electronic device 24b may include a plurality of I/O units (or electrical I/O units) 40b at the surface 241 of the electronic device 24b. The electronic device 24b (or the I/O units 40b) may be electrically connected with the component 12 (or the circuit structure 12r2) through the electrical connection elements 28b. The electronic device 24b may be electrically connected with the electro-optic conversion unit 12a through a circuit structure (or an I/O unit) 12r3. The circuit structure 12r3 may be embedded in the component 12.

The optical connection elements 28a may include optical bumps. The electrical connection elements 28b may include solder balls, controlled collapse chip connection (C4) bumps, a ball grid array (BGA), or a land grid array (LGA).

The component 12 may be configured to receive an optical P11 from the optical component 15, transmit the optical signal 11 (or optical signals P22 by splitting the optical signal P11 into a plurality of beams (i.e., optical signal P12)) to the photonic component 24a through the optical connection element 28a. The photonic component 24a may be configured to process the optical signal P22. The photonic component 24a may include a photonic computing processer. The photonic component 24a may include one or more photonic devices to modulate, polarize, and transmit the optical signal P22. The photonic component 24a may be configured to generate an optical signal P23 from the optical signal P22 and then transmit the optical signal P23 to the component 12 (or the I/O units 12g2 of the waveguide 12w2) through the optical connection elements 28a.

The electro-optic conversion unit 12a may be configured to receive the optical signal P23 from the photonic component 24a through the waveguide 12w2. The electro-optic conversion unit 12a may be configured to convert the optical signal P23 to an electrical signal E21 and transmit it to the circuit structure 12r3. The circuit structure 12r3 may transmit the electrical signal E21 to the electronic device 24b which may modulate or amplify the electrical signal E21 to be an electrical signal E22. The electronic device 24b may be configured to transmit the electrical signal E22 to the electronic component 13 through the circuit structure 12r2. In some embodiments, the electro-optic conversion unit 12a may be configured to convert the optical signal P23 to an electrical signal E23 and transmit it to the circuit structure 12r1. The circuit structure 12r1 may transmit the electrical signal E23 to the wiring structure 11.

The photonic component 24a and the electronic component 13 process different types of signals. The photonic component 24a may process optical signals and the electronic component 13 may process electrical signals. The photonic component 24a may be configured to read and/or write the data stored in the electronic component 13 through the component 12. In particular, the component 12 may be configured to convert a first command (e.g., the optical signal P23 from the photonic component 24a) to a second command (e.g., the electrical signal E22) that is compatible with the electronic component 13. In some embodiments, the electronic component 13 may transmit data (electrical signals) to the component 12, based on the commands from the photonic component 24a (i.e., P23 and E22), and then the data is converted from electrical signal(s) to optical signal(s) by the electro-optic conversion unit 12a and transmitted to the photonic component 24a. The component 12 provides a hybrid transmission path (at least including electrical and optical transmission paths) for bidirectional transmitting signals between the photonic component 24a and the electronic component 13. Thus, the component 12 is a bridge, buffer, or an interface that realizes the communication between a photonic component, element or structure (e.g., the photonic component 24a) and an electronic component, element or structure (e.g., electronic component 13). With the nature of high bandwidth of optical transmission brought by the photonic component 24a and the component 12, the bandwidth and efficiency of the data transmission in the package structure 5 may significantly increase.

In some embodiments, with the optical I/O units 12g1 and 12g2 and the electrical I/O units 12p2 and 12p3 at the same surface, i.e., the surface 121, the component 12 is capable of connecting a photonic component, element or structure (e.g., the photonic component 24a) and an electronic component, element or structure (e.g., the electronic component 13) arranged at the same side of the component 12.

The package structure 5 may include the blocking structure 30A in FIG. 3 or the blocking structure 30B in FIG. 4 and some detailed descriptions may refer to the corresponding paragraphs and are not repeated hereinafter for conciseness.

FIG. 5A is a bottom view of a set of devices (e.g., the set of devices 24), which can be viewed as optical chiplet, according to some embodiments of the present disclosure. The electronic device 24b may partially surround the photonic component 24a. Each of the optical connection elements 28a may be connected to the corresponding one of the I/O units 40a of the photonic component 24a. The I/O units 40a of the photonic component 24a and the optical connection elements 28a may be arrayed. The electrical connection elements 28b may be connected to the corresponding one of the I/O units 40b of the electronic device 24b. The I/O units 40b and the connection elements 28b may be arrayed. The electronic device 24b may include a plurality of I/O units 40c at the surface 241 of the electronic device 24b. A plurality of connection elements 28c may be electrically connected to the electronic device 24b (or the I/O units 40c). The I/O units 40c and the connection elements 28c may be arrayed. The connection elements 28b and 28c may surround the optical connection elements 28a. The connection elements 28c may be connected to the corresponding one of the I/O units 40c. The connection elements 28c may be configured to transmit a power signal and the connection elements 28a may be configured to transmit a data signal.

FIG. 5A illustrates one arrangement of the connection elements 40a, 40b, 40c but does not limit the scope of the present disclosure. As illustrated in FIG. 5A, the connection elements 40a, 40b, 40c may be arranged in different regions from the bottom view.

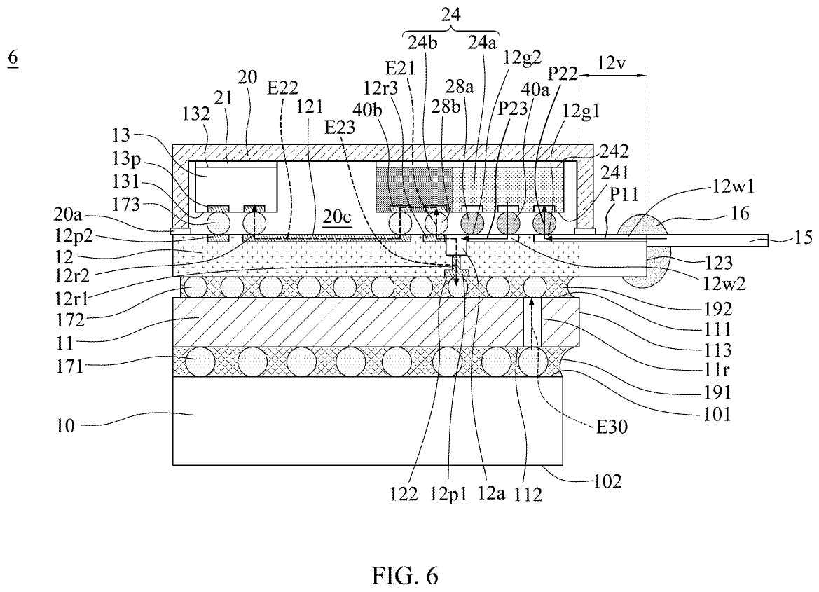

FIG. 6 is a cross-sectional view of a package structure 6 according to some embodiments of the present disclosure. The package structure 6 in FIG. 6 is similar to the package structure 5 in FIG. 5 with differences therebetween as follows.

The package structure 6 may further include a lid 20 disposed over the component 12. The lid 20 may be attached to the surface 121 of the component 12 through an adhesive material 20a. The lid 2 may define a cavity 20c to accommodate the photonic component 24 and the electronic component 13. The lid 20 may be attached to the surface 242 of the set of devices 24 and the surface 132 of the electronic component 13 through an adhesive material 21. The adhesive material 21 may be or include thermal interface material (TIM). The adhesive material 21 may include a conductive glue, such as tin-based glue. The lid 20 may function as a heat sink. The lid 20 may be configured to dissipate the heat from the package structure 6 to an environment. In particular, the lie 20 may dissipate the heat from the set of devices 24 and the electronic component 13 through the adhesive material 21.

Spatial descriptions, such as “above,” “below,” “up.” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a bridge component;
a photonic processing unit disposed over the bridge component; and
an electrical device disposed over the bridge component,
wherein the bridge component is configured to optically couple with the photonic processing unit and electrically connect with the electronic component.

2. The package structure of claim 1, wherein the bridge component has a first surface facing the photonic processing unit and comprises a plurality of optical I/O units and a plurality of first electrical I/O units disposed at the first surface of the bridge component.

3. The package structure of claim 2, wherein the bridge component comprising a plurality of second electrical I/O units at a second surface opposite to the first surface.

4. The package structure of claim 2, wherein the photonic processing unit is configured to process an optical signal transmitted through the bridge component.

5. The package structure of claim 2, further comprising a plurality of optical connection elements disposed between the photonic processing unit and the optical I/O units of the bridge component.

6. The package structure of claim 2, further comprising a plurality of electrical connection elements disposed between the electronic component and the first electrical I/O units of the bridge component.

7. The package structure of claim 1, wherein the photonic processing unit is configured to communicate with the electronic component through the bridge component and the bridge component comprises a conversion unit to convert electrical signal(s) to optical signal(s) or convert optical signal(s) to electrical signal(s).

8. The package structure of claim 1, further comprising an optical fiber optically coupled with the bridge component and communicating with the photonic processing unit.

9. The package structure of claim 8, wherein the bridge component comprises an overhang portion and the optical fiber is optically coupled with the bridge component at the overhang portion.

10. The package structure of claim 1, further comprising a modulator disposed over the bridge component, a plurality of optical connection elements connecting the photonic processing unit with the bridge component, and a plurality of electrical connection elements connecting the modulator with the bridge component.

11. The package structure of claim 1, further comprising a heat sink attaching to the photonic component and the electronic component.

12. A package structure, comprising:
a signal transmission component comprising a plurality of optical I/O units and a plurality of electrical I/O units; and
an electro-optic conversion unit configured to convert optical signals to electrical signals or convert the electrical signals to the optical signals,
wherein the signal transmission component comprises a first transmission path configured to transmit the optical signals from or to the optical I/O units, and a second transmission path configured to transmit the electrical signals from or to the electrical I/O units, and
wherein the electro-optic conversion unit connects with the first transmission path or the second transmission path or both.

13. The package structure of claim 12, wherein the signal transmission component further comprises a third transmission path configured to transmit the optical signals from or to an optical fiber.

14. The package structure of claim 13, wherein the signal transmission component further comprises a fourth transmission path configured to transmit a power signal.

15. The package structure of claim 13, wherein the optical fiber transmits the optical signal to a photonic component through the first transmission path.

16. The package structure of claim 14, wherein the electro-optic conversion unit is configured to receive the optical signals from a photonic component through the optical I/O units, convert the optical signals to the electrical signals, and transmit the electrical signals to an electronic component through the electrical I/O units.

17. The package structure of claim 12, wherein the electro-optic conversion unit is embedded in the signal transmission component.

18. A package structure, comprising:
a bridge component, comprising a first surface and a second surface different from the first surface;
a photonic processing unit disposed over and optically connecting with the first surface of the bridge component; and
an optical component optically connecting with the second surface of the bridge component, wherein the optical component communicates with the photonic processing unit through the bridge component.

19. The package structure of claim 18, wherein the bridge component comprises a third surface opposite to the first surface, wherein the third surface is configured to electrically connect with a wiring structure.

20. The package structure of claim 19, wherein the first surface of the bridge component is further configured to electrically connect with an electrical component.
